(19) United States
(12) Patent Application Publication
(10) Pub. No.: US 2008/0057687 A1
(43) Pub. Date: Mar. 6, 2008

(54) Selective area deposition and devices formed therefrom

(75) Inventors: Andrew T. Hunt, Atlanta, GA (US); Jan Tzyy-Jiuan Hwang, Alpharetta, GA (US)

Correspondence Address: nGimatCo.;MICROCOATING TECHNOLOGIES, INC., 5315 PEACHTREE INDUSTRIAL BLVD, ATLANTA, GA, 30341-2107, US

(73) Assignee: nGimat Co., a Georgia Corporation

(21) Appl. No.: 11/514,788

(22) Filed: Sep. 1, 2006

(51) Int. Cl. H01L 21/20

(52) U.S. Cl. 438/584

(57) ABSTRACT

Patterned thin film layers (12) are applied to a substrate (10) surface by masking selective areas of a substrate surface, e.g., with a printed pattern (11) of a material such as an oil, and vapor-depositing thin film material. The masking material is subsequently removed.

### FIELD OF THE INVENTION

The present invention is directed to selective area deposition of thin films, including, but not limited, to thin films useful for forming electronic circuitry.

### BACKGROUND OF THE INVENTION

Circuitry traces of printed electronic circuitry are typically formed by a photolithographic process. In a typical process for forming a layer of circuitry traces, a blank is prepared comprising a metal layer, typically copper, on a dielectric substrate, such as a fiberglass-epoxy composite. A layer of photoresist is applied to the metal layer, and patterned artwork laid over the photoresist layer. Then the photoresist is exposed to actinic radiation so as to affect the exposed portions of the photoresist. Then the photoresist is developed with an appropriate developing solution that washes away exposed portions of the photoresist, in the case of negative-acting photoresists, and non-exposed portions, in the case of positive-acting photoresists. Next, the metal layer is etched to remove the metal from the portions of the metal layer from which resist has been removed. Finally, the remaining photoresist is stripped.

Advances in resists and photolithography have yielded finer and finer resolution in electronic printed circuitry, and photolithography has many advantages and is well studied as a method of producing a printed circuit. Nevertheless, it can be seen that the printing of electronic circuitry is a multi-step process, each step requiring time, effort and a variety of materials. Specific chemicals, some of them harsh, and all requiring ultimate disposal, are required for producing the photoresist layer, developing the photoresist layer, etching the metal layer, and stripping the remaining photoresist layer.

U.S. Pat. No. 6,210,592 describes thin film layers of resistive materials that can be deposited, for example, by combustion chemical vapor deposition (CCVD) and patterned by photolithography to form patches of resistive material. When used in conjunction with circuitry traces, a plurality of thin film resistors may be formed by this technique. Again, multi-step photolithography steps are used for forming the patterned resistive material layer.

U.S. Pat. No. 6,207,522 describes thin film layers of dielectric materials that can be deposited, for example, by CCVD and used as the dielectric material in thin film capacitors. This patent describes patterning of the dielectric material layer by photolithographic processes. However, patterning of dielectric materials often proves more difficult than patterning metal circuitry layers or metal-based resistive material layers. Accordingly, dielectric layers in thin film electronic circuitry composites may be left as un-patterned planer layers with capacitive electrical pathways formed between conductive (and/or resistive) layers on both sides of the dielectric layers. In some cases it would be desirable to form capacitive circuitry paths horizontally across the dielectric material layer rather than or in addition to vertically through the dielectric material layer. Accordingly, a simple method of patterning dielectric layers would be desirable.

U.S. Pat. No. 6,212,078 describes multi-layer nanolaminated thin film circuitry traces. In this patent, nanolaminated structures containing conductive layers, resistive layers, and dielectric layers are used to form complex electronic circuitry containing conductive pathways, resistors, capacitors, and inductors. In the structures described in this patent, certain layers are patterned by photolithographic techniques, such as those described above. Other layers are left un-patterned with subsequently formed via holes used to interconnect layers and define electrical pathways, e.g., resistive and capacitive pathways. It would be desirable to provide simpler ways of patterning thin films so as to reduce processing steps, reduce the use of processing chemicals, and provide greater flexibility in the design of multi-layer thin film circuitry.

While the techniques described herein may not be as fully developed as photolithography techniques and may not yet provide the same resolution as the most advanced photolithographic techniques, the processes have reduced steps, and use fewer steps and reduce the use of chemicals. In many cases the techniques described herein may provide greater flexibility of circuitry design. The techniques are especially useful for forming relatively inexpensive, simple electronic circuitry that may be designed for a variety of applications. Further, it is possible to form entire circuitry composites, including conducting, resistive, capacitive, and inductive elements of thin film materials, or at least flexible materials.

While initial use of the patterning techniques of the present invention may be first applied in formation of thin film electronic circuitry, and while the invention will be described initially in reference thereto, the patterning techniques are applicable to a wide variety of materials that may be deposited by vapor deposition processes.

Such uses include artistic uses as well as functional purposes. CCVD, as described in U.S. Pat. Nos. 5,997,956 and 5,652,021, is useful for depositing certain metals in metallic (zero valence) form. This is especially true for noble metals, such as platinum and gold. The deposited layers may be very thin, e.g., on the nanometer or micron thickness levels, and therefore decorative layers of these precious materials may be deposited with minimal use of the noble metal.

### SUMMARY OF THE INVENTION

In accordance with the invention, vapor-deposited thin films are deposited on a substrate that is masked, the films depositing only on the unmasked area. The mask may be a mechanical mask. A preferred mask is a printed chemical substance that may be applied in a pattern by a variety of printing techniques, such as silk screening and/or roller printing. The vapor deposited thin film is then applied, the thin film material either adhering or depositing only in the unmasked regions. The masking substance is then removed, leaving a patterned thin film. If no functional deposition occurs on the mask, then it could remain.

Multiple layers of patterned thin film may be applied by this method, such multi-layer patterned laminates being applied, for example, to form thin film electronic circuitry including circuitry elements, including traces and inductors, and passive components, including resistors.

The masking procedure of the present invention involves substantially fewer processing steps than photolithographic processes. In forming printed circuitry, even if resolution is sacrificed to some extent, economic benefits may be realized. Furthermore, because of the flexibility in forming devices with multiple layers of patterned circuitry components, even if resolution is lost in some cases, an entire circuitry device may be even smaller than is practically achievable by such devices produced by photolithographic processes.

The masking material may be a simple chemical, such as a common, environmentally safe oil. The chemical for removing the masking chemical may be a common, environmentally friendly solvent, such as isopropyl alcohol, or an aqueous detergent solution.

Alternative masks include photoresist on the substrate prior to deposition, ink printing techniques, e.g., ink jet, and blank masking with selective area removal via photons or electrons, e.g., laser, x-ray, etc. ablation. Such techniques may produce very fine resolution.

A further advantage of the present technique is the accuracy and precision that are inherent to devices formed that do not require post processing (i.e. etching). As the material forming the device (for example, resistive material for resistors), is deposited, the desired characteristic (i.e. resistance) can be measured either continuously, or periodically. Once the desired value is achieved, the deposition is terminated. As no etching of the material is required, this value remains the same, resulting in a method to produce resistors or other components with improved accuracy and reduced manufacturing and processing costs, when compared to other methods of forming accurate components (such as laser trimming).

### BRIEF DESCRIPTION OF THE DRAWINGS

FIGS. 1a-1f illustrate the formation of a simple electronic circuitry comprising a plurality of resistive material pads interconnected by electronic circuitry. This resistor elements formed by this method may be used for selective area micro-heating;

FIG. 1a is a cross-sectional view of a metal foil layer to which a pattern of masking material has been applied to one surface.

FIG. 1b is a cross-sectional view of the structure of FIG. 1a on which resistive material has been deposited on the masked surface.

FIG. 1c is a cross-sectional view of the structure of FIG. 1b in which the masking material has been removed leaving patterned resistive material on the surface of the foil.

FIG. 1d is a cross-sectional view of the structure of FIG. 1c in which the patterned resistive material is embedded in a material that provides a support, e.g., a flexible support.

FIG. 1e is a cross-sectional view of the structure of FIG. 1d in which the foil layer has been patterned, e.g., by a standard photolithography technique.

FIG. 1f is a plan view of the formed circuit in which discrete thin film resistors are connected to electronic circuitry traces.

FIGS. 2a-2d illustrate the formation of a flexible printed circuit that has a plurality of thin film layers, including a plurality of patterned thin film layers produced in accordance with the present invention.

FIG. 2a is a cross-sectional view of a support sheet, e.g., a flexible support sheet, on which has been applied a patterned layer of electrically conductive, e.g., copper, circuitry traces.

FIG. 2b is a cross-sectional view of the structure of FIG. 2a on which has been deposited a continuous layer of dielectric material.

FIG. 2c is a cross-sectional view of the structure of FIG. 2b on which a patterned layer of resistive material has been deposited.

FIG. 2d is a cross-sectional view of the structure of FIG. 2c on which a patterned layer of electrically conductive material has been deposited.

FIG. 3A shows a cross-section of a two-layer laminate comprising an electrically conductive metal foil layer and a thin film layer of resistive material.

FIG. 3B shows a cross-section of the two-layer laminate of FIG. 1A in which the layer of resistive material has been patterned to produce discrete patches of resistive material.

FIG. 3C shows a cross-section of the patterned laminate of FIG. 1B adhered to a support sheet by an adhesive layer.

FIG. 3D shows the laminate of FIG. 1C after the electrically conductive layer has been patterned.

FIG. 4A shows a cross-section of a patterned laminate as shown in FIG. 1B adhered to a relatively thick embedding and supporting layer and to a removable backing or cover sheet.

FIG. 4B shows the laminate of FIG. 2A with the backing sheet removed.

FIG. 4C shows the laminate of FIG. 2B after the electrically conductive layer has been patterned.

FIG. 5 is a plan view of electronic circuitry in which discrete patches of resistive material are connect-able to an outside power source through printed electronic circuitry, as per FIGS. 1D or 2C.

FIG. 6 is a cross-section of a laminate, similar to that of 1C, except that the resistive material layer has not been patterned.

FIG. 7 is a cross-section of a laminate similar to FIG. 2A except that the resistive material layer has not been patterned.

### DETAILED DESCRIPTION OF CERTAIN PREFERRED EMBODIMENTS

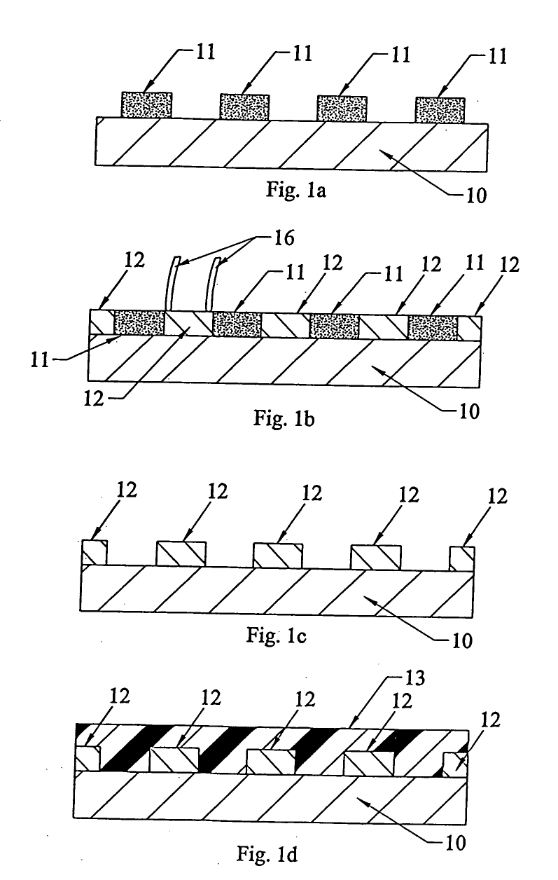

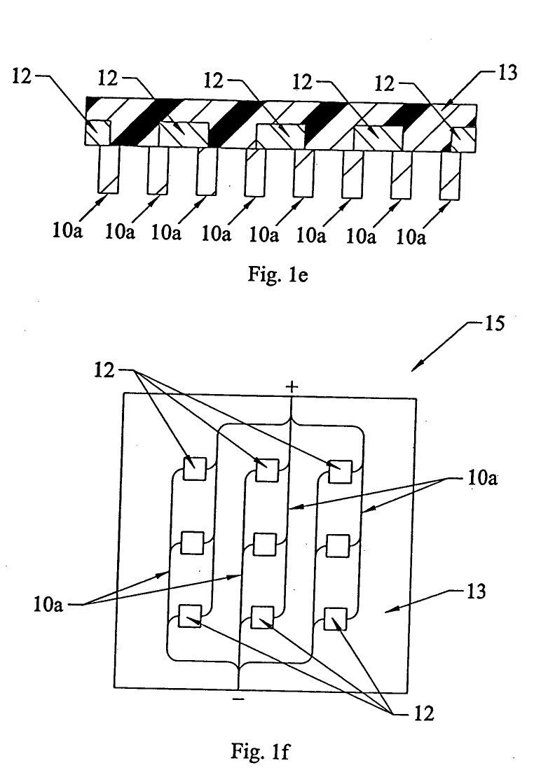

Illustrated in FIG. 1a is a cross-sectional view of a self-supporting, electrically conductive metal foil 10, such as copper foil, is coated with a patterned layer of masking material 11. Alternatively the substrate may be all or part insulating material (such as polyimide). The masking material of layer 11 could be a mechanical mask, but is preferably an adhering substance, such as a printed layer of oil. To this structure, as shown in FIG. 1b is vapor-deposited, e.g., by CCVD, a layer 12 of electrically resistive material. An example of an electrically resistive material that can be deposited as a thin film by CCVD is a platinum/silica mixture, as described in U.S. Pat. No. 6,212,078. The resistive material 12 adheres to the foil 10 in the unmasked areas, but does not deposit on the masking material 11. Accordingly, the masking material 11 may be removed by an appropriate solvent, as seen in FIG. 1c, leaving patches of resistive material 12.

During the deposition of resistive material 12, probes 16 can be used to measure the resistance of one or more of the resistive patches that are grown on portions of the substrate that are insulating (or an insulating film can be between the substrate and the resistive patches). This is done by passing an electrical current through the patch 12 via the probes 16. When the desired resistance is achieved, deposition of the resistive material 12 is terminated, resulting in a highly accurate resistance value. Probes 16 may continuously monitor the resistance of the patch(es), or may move away from the deposition area, and periodically moved back into the monitoring position (as shown), to avoid interfering with the deposition process. For some materials, it may be desired to measure other characteristics (such as transparency), and to control the deposition based on these in-situ measurements.

After the masking material 11 is removed, a backing material 13 is applied to embed the resistive material patches 12 as seen in FIG. 1d. This backing material 13 may be a curable epoxy resin, such as that known as pre-preg or FR-4. The backing material 13 is applied to a sufficient thickness above the resistive material patches 13 such that when cured, the backing material 13 has sufficient structural integrity to support the structure as it is formed. Alternatively, the backing material 13 may be applied to a thickness just sufficient to cover the resistive material patches 12 and act as an adhesive to a supporting sheet of polymeric material (not shown). The backing material 13 (or backing material plus support sheet) may be flexible or inflexible, depending upon thickness. Some applications may call for a flexible circuit, others an inflexible circuit.

To complete the circuit, the metal foil layer 10 is now patterned into circuitry traces 10a, as seen in FIG. 1e. A pair of such circuitry traces contacting spaced-apart locations on a resistive material patch 12 define an electrically resistive pathway.

A simple device 15 formed using the method of the present invention is illustrated in FIG. 1f. In this device, a plurality of resistive material patches 12 on a support material 13 are each interconnected at circuitry traces 10a of opposite electrical polarity. The electrical current through the electrically resistive patches 12 generate heat. Thus device 15 may be a selective, micro-area heating pad as seen in FIG. 1f. A large number of miniature selective area heating pads may be formed starting with a sheet of foil and subsequently divided into multiple discrete devices.

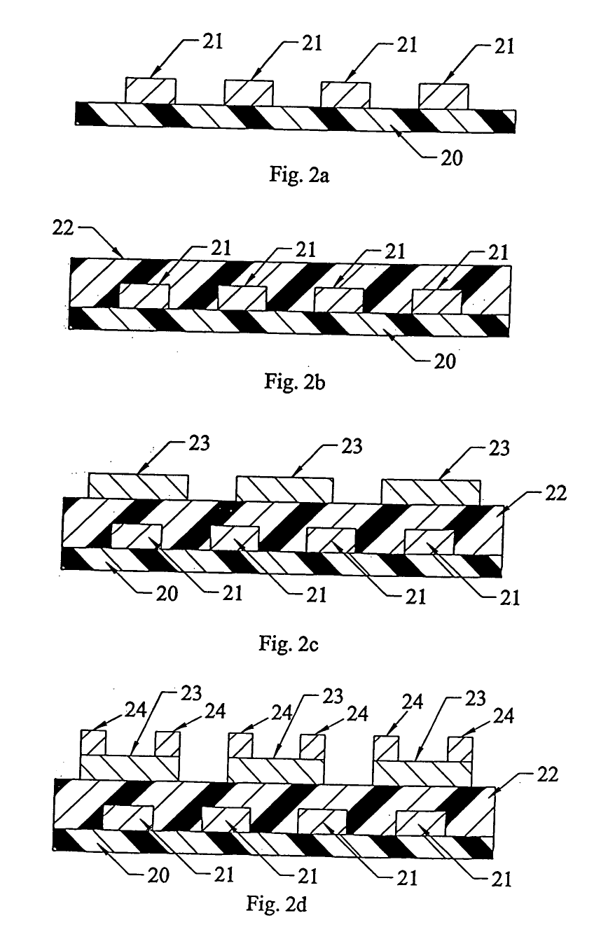

Formation of a complete electrical circuit by vapor deposition layers is illustrated with respect to FIGS. 2a-2d.

In FIG. 2a, on a sheet 20 of polymeric material, e.g., flexible polymeric material, electrically conductive circuitry traces 21 are produced by masking a surface of the polymeric material and then vapor-depositing an electrically conductive metal. The polymeric support sheet 20 for electrical applications may be polyimide or polyimide/amide, these materials exhibiting heat stability, but other polymers may be used, depending on the amount of heat expected to be generated during the deposition and subsequently by the circuitry. Noble metals, such as platinum or gold may easily be deposited by a number of processes including CCVD. More oxidation-susceptible, electrically conductive metals, such as copper or nickel, may be deposited by CCVD under reduced atmosphere, as described, for example, in U.S. Pat. No. 5,652,021 and European patent document EP-0976847.

Next, as seen in FIG. 2b, a layer 22 of dielectric material is deposited so as to cover the circuitry traces 21. The dielectric material may be an inorganic material, such as an oxide, e.g., silica, as described in U.S. Pat. No. 6,207,522, or a polymeric material, such as polyimide. Such polymer deposition is described in U.S. Pat. No. 6,939,576.

As seen in FIG. 2c, by patterned deposition in accordance with the invention, patches 23 of resistive material are formed on the dielectric material, and then, as seen in FIG. 2d, by patterned deposition in accordance with the invention is formed a further patterned layer of circuitry traces 24. In this circuitry embodiment, the dielectric layer 22 is continuous; however, in other circuitry designs, the dielectric material layer may be similarly patterned.

Resistive electrical pathways are formed between circuitry traces 24 connecting resistive patches 23 at spaced apart locations, and capacitive electrical pathways are formed between resistive patches 23 and circuitry traces 21 through dielectric layer 22.

The circuitry trace patterns of 21 and/or 24 may also be patterned to form inductive elements.

The illustrated circuitry of FIG. 2d is only one of any number of circuitry arrangements that may be simply fabricated using the method of the present invention.

Again, the method of depositing patterned thin film layers is not limited to electronic circuitry, but may be used to apply patterned thin film layers of any number of thin film material.

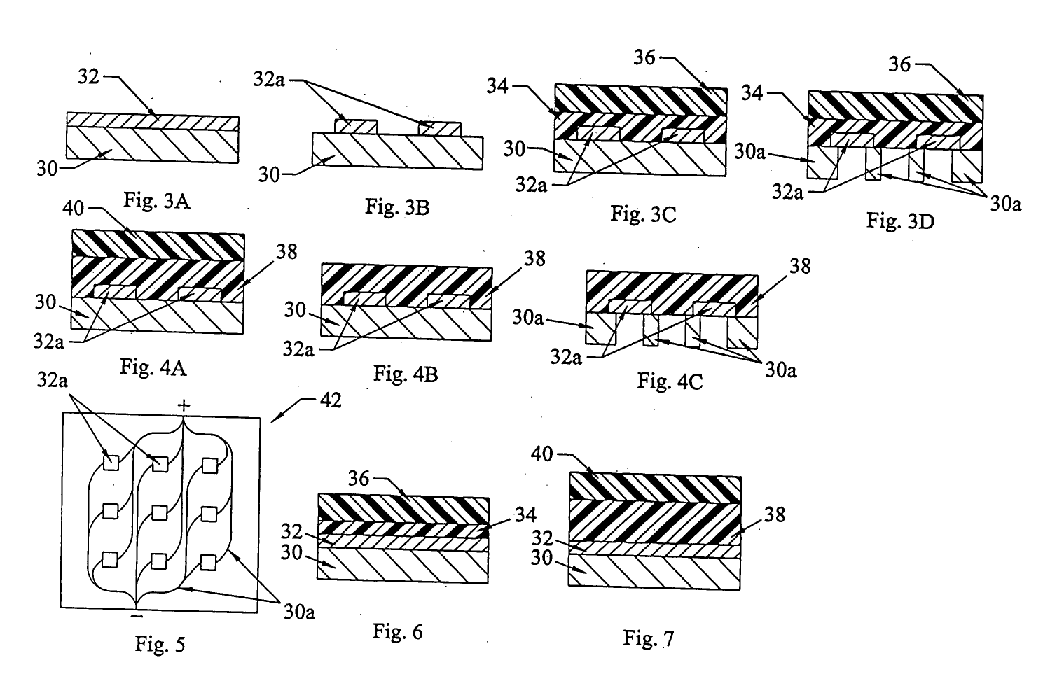

Illustrated in FIG. 3A is a cross-section of a two-layer laminate comprising an electrically conductive metal foil layer 30 and a thin film electrically resistive layer 32 formed thereon. The foil layer is selected so as to be electrically conducting and also to be etchable by standard techniques for printing electronic circuitry, copper foil or nickel foil being examples of such foils. The foil layer 30 for the fabrication method of FIGS. 3A-3D need only be sufficiently thick to be self-supporting and is preferably relatively thin so that a high resolution of printed circuitry can be patterned from this layer in a later step. Typically, the metal foil layer 30 is between about 10 and about 100 microns thick, generally between about 17.5 and about 70 microns thick.

Layer 32 is formed of a material that is electrically conductive, but has a relatively high electrical resistance relative to that of the foil layer 30. Preferably the layer 32 is formed of such material and such thickness as to have a resistivity of between about 1 and about 15 ohms per square. U.S. Pat. No. 6,210,592 describes formation of thin films of resistive material comprising a metal, e.g., platinum, and a dielectric, e.g., silica, and methods of fabricating discrete patches of resistive material from such resistive material layer patches. In the U.S. Pat. No. 6,210,592, the resistive material layer is deposited by combustion chemical vapor deposition (CCVD), but the layer 32 of resistive material for use in the present invention may be fabricated by any of known thin film techniques, such as sputtering and evaporation. The resistive material is a thin film, typically ranging from about 0.1 to about 10 microns in thickness.

Shown in FIG. 3B is the laminate of FIG. 3A in which the resistive material layer 32 of FIG. 3A has been patterned so as to form discrete resistor patches 32a. Such patterning may be done by standard photolithographic techniques, such as are described in U.S. Pat. No. 6,210,592.

To the laminate of FIG. 3B, and as illustrated in FIG. 3C, is applied a thin layer 34 of adhesive, and to this is laminated a flexible support sheet 36, preferably a polymeric material, such as polyimide. The adhesive 34 in this embodiment need only be thick enough to cover the patches 32a of resistive material, but, the adhesive, naturally, fills the space between the patches 32a. One material that may be used for the adhesive 34 is a curable epoxy, such as is sold as “pre-preg” or “FR-4”. The support sheet 36 is laminated to the structure using heat and pressure, the heating acting to cure the adhesive layer 34. Alternatively, for certain embodiments of the invention, as will be described hereinafter, both the adhesive for layer 34 and the support sheet 36 may be formed of thermoplastic material.

With the support sheet 36 laminated to the structure, the foil layer 30 is no longer needed for structural support, and the foil layer is patterned, e.g., by photolithographic techniques, to form circuitry traces 30a, a pair of circuitry traces 30a contacting spaced-apart locations on each resistive material patch so as to form a resistive pathway that produces tissue-perforating heat when current is supplied to the circuitry.

Illustrated with respect to FIGS. 4A, 4B, and 4C is an alternative method of fabricating the heating device of the present invention. In this case, after the resistive material has been patterned into patches 32a, a relatively thick layer 38 of adhesive material is applied, followed by lamination to a backing sheet 40 of relatively low adhesion to the adhesive layer 38 as seen in FIG. 4A. In this case, the adhesive layer 38 is intended to provide the support to the structure, and the backing sheet 40 is intended to be removed subsequent to lamination and curing of the adhesive layer 38. The structure with the backing sheet 40 removed is shown in FIG. 4B. Subsequently the foil layer 30 is patterned to form discrete resistive patches 30a as seen in FIG. 4C. In this case, the adhesive layer 38 is applied to a thickness of between about 1 and about 500 microns above the resistive material patches 32b. The removable backing sheet 40 may be formed of wax paper, Tedlar® (polyvinylfluoride), or the like, having low adhesion to the adhesive layer.

Either by the process of FIGS. 3A-3D or 3A, 4A-4C, a resistive device 42 is formed, as illustrated in FIG. 5. In this device 42 a plurality of resistive material patches 32a are each connected to a pair of circuitry traces 30a of opposite electrical polarity. These can be connected to an external power supply, such as a battery or transformer, so as to cause the resistive patches to produce the desired heat. For micro-perforating human skin, it is desired that the resistor patches produce localized temperatures of about 400° C. to about 800° C. for short periods of time. For other living membranes or for other purposes, lower temperatures may suffice. For re-usable devices, such as for bubble jet inkers, the device 42, including the resistive patches 32a and circuitry traces 30a, should be robust. For some one-time use fluid delivery devices, such as may be used to apply a drug through a living membrane, it may be acceptable or even desirable that the circuitry burn out during the heating step. If the circuitry burns out, there is no possible second triggering of the device.

The device 42 is formed of thin flexible materials and, as such, conforms to the surface, e.g., skin, to which the device is applied. The degree of flexibility required of the device is dependent upon the surface contours to which the device or pad 42 is applied.

In the illustrated circuitry of device 42, all the patches 32a are connected in parallel so as to activate all of the resistive patches at once. However, the circuitry traces could be designed such that selective resistive patches could be activated individually. Such could be useful for timed, sequential delivery of living tissue, e.g., to deliver drug doses at predetermined periodic intervals. A large array of closely spaced resistive patches could be connected to a circuitry grid such that selected patches could be activated in a pattern, e.g., to burn a pattern in wood or another substrate, or to deliver ink in a pattern for tattooing purposes. Such an array could even be connected to a computer such that the device could be used for burning a computerized image into a surface or tattooing the skin with a computer generated device. The heating device could overlie a laminate of a support sheet and a surface-facing melt-able solid material. Upon selective activation of resistive patches, an image of melted material could be applied to a surface.

The area of the resistive material patches 32a may as small as 1 mm² and as large as required for the application. For delivery of fluid through the human skin, the area of the patches 32a typically ranges from about 1 to about 1000 mm².

In FIG. 6 is illustrated a laminate comprising a metal foil 30, a thin film layer 32 of electrically resistive material, an adhesive layer 34 and a support sheet 36. In FIG. 7 is illustrated a laminate comprising a metal foil 30, a thin film layer 32 of electrically conductive material. In this case, the laminate is formed without intermediate patterning of the thin film resistive material layer. In either of these cases, the foil layer 30 would be first circuitized, and then, in exposed areas, the resistive material layer 32 is patterned. This order of patterning has the disadvantage in that the resistive material layer 32 below the traces 30a of conductive material cannot be patterned, thereby reducing the flexibility of circuitry design. On the other hand, laminates as are shown in FIG. 6 and FIG. 7 may be more easily mass produced and supplied to a customer who may then design an appropriate circuitry pattern according to need.

While currently envisioned circuitry formation is described above, one with ordinary skill in the art will recognize that a variety of lamination and ciruitization steps performed in a number of different orders may be utilized to form micro-heating devices in accordance with the invention.

While a very important utility for the present invention is for drug delivery, the invention could be applied to any heat sensitive utility in which localized controlled heating to high levels is required. The key is where the exact spatial distribution or very fine control of the amount of surface is at a specific temperature range is needed for optimal performance and control. Such other application include but not limited to thermal writing and marking, thermal ablation or transfer of films of material, fine thermally controlled reaction surfaces, displays, and thermal control of mechanical, electrical or optical properties.

### EXAMPLE 1

On a copper surface, a thin film of platinum was deposited by combustion chemical vapor deposition (CCVD) according to the method taught in U.S. Pat. No. 5,652,021. Inadvertently, a finger print was left on the copper surface. The platinum deposited uniformly on the surface, except where the finger print was left; no platinum deposited on the oily surfaces of the print.

What is claimed is:

1. A method of depositing a patterned thin film layer on a surface of a substrate comprising:
masking selected areas of substrate, and
vapor depositing a thin film on said masked substrate, whereby said thin film deposits on said substrate only on unmasked areas of said substrate.

2. The method of claim 1 wherein said masking material is removed after said thin film is deposited.

3. The method of claim 1 wherein said masking material is a chemical that is printed on said substrate surface.

4. The method of claim 1 wherein said thin film is formed of electrically conductive material.

5. The method of claim 1 wherein said thin film is an electrically resistive material.

6. The method of claim 1 wherein said thin film is a dielectric material.

7. The method of claim 1 wherein said masking material is an oil.

8. The method of claim 1, further comprising the step of measuring a characteristic of said thin film during said vapor deposition, and terminating said vapor deposition when a desired value of said characteristic is reached.
